(19) United States
(12) Patent Application Publication
(10) Pub. No.: US 2010/0113100 A1
(43) Pub. Date: May 6, 2010

(54) Electronic device having a clamshell configuration

(75) Inventors: Roger W. Harmon, Crystal Lake, IL (US); Michael J. Lombardi, Mundelein, IL (US); Michael Spence, Libertyville, IL (US)

Correspondence Address: THE WATSON INTELLECTUAL PROPERTY GROUP, PLC, 3133 HIGHLAND DRIVE, SUITE 200, HUDSONVILLE, MI, 49426, US

(73) Assignee: Motorola, Inc.

(21) Appl. No.: 12/290,805

(22) Filed: Nov. 4, 2008

(51) Int. Cl. H04M 1/00; H05K 5/00

(52) U.S. Cl. 455/566; 361/679.01; 455/575.3; 455/569.1

(57) ABSTRACT

An electronic device comprising a first housing and a second wherein, the first and second housings have outward surfaces. One of the outward surfaces includes an electronic display and the other of the outward surfaces includes a keyboard or other input device. A hinge couples the two housing elements together. In a collapsed orientation the outward surfaces of the housing elements are exposed and face away from each other. In a fully deployed orientation, the display and the keyboard are in a side by side orientation. In a partially deployed orientation, the housing containing the display surface is angled away from the housing containing the keypad and the housing containing the keypad acts as a base to hold the angled display open for viewing purposes.

### BACKGROUND OF THE DISCLOSURE

1. Field of the Disclosure

The disclosure relates in general to an electronic device, and more particularly, to an electronic device having a clamshell configuration. The electronic device includes an electronic display and a keyboard on opposing outward surfaces of the clamshell configuration. In certain embodiments, the clamshell configuration comprises a mobile telephone, but the disclosure is not limited to mobile telephones.

2. Background Art

Electronic devices, such as mobile telephones and the like, include a number of different configurations. A clamshell configuration which includes two components that are hinged together at one side edge is a common type of configuration for electronic devices. Typically, the inner surfaces house an electronic display and a keyboard such that the device must be rotated to expose each of these elements.

While such configurations are quite common, there are drawbacks to these configurations. First, the clamshell configuration, in certain devices such as mobile telephones typically requires the use of an additional display which is on one of the outward surfaces of the device. This is so that the user can access an electronic display and utilize an electronic display without deploying the phone and rotating the two components. For example, the additional display is utilized so as to allow the user to make and receive calls without opening the clamshell configuration.

Other common device configurations are often referred to as sliders. In such a configuration, one of the two components is slid on rails relative to the other component. Typically, the sliding exposes the inward surface of the second component, exposing a keyboard. The electronic display in such a configuration is typically positioned on the outward surface of the first, or upper, component.

While such a configuration allows for the use of a single electronic display, the slide mechanism occupies an excess amount of space to properly operate. As such, slider configurations often result in an excessively thick electronic device and are unacceptable to users. Thus, while the need for additional electronic displays may be eliminated, the resulting thickness of the device often renders such a configuration undesirable.

It would be desirable to provide for an electronic device which overcomes the deficiencies of the prior art devices with respect to both configuration and minimization of components.

### SUMMARY OF THE DISCLOSURE

The disclosure is directed to an electronic device, such as a mobile phone. It will be understood that the example of a mobile phone is not to be deemed limiting, and is used for exemplary purposes only. The disclosure is not limited to mobile phones, or to what are termed as smartphones, and has substantially broader applications.

In an exemplary embodiment, the electronic device comprises a first housing element and a second housing element. The first housing element includes an inward surface and an outward surface and a side edge. The outward surface of the first housing element includes an electronic display. The second housing element includes an inward surface and an outward surface and a side edge. The outward surface of the second housing element includes a keyboard.

A hinge couples the first housing element and the second housing element about the respective side edges of the first and second housing elements. In a collapsed orientation, the inward surfaces of the first housing element and the second housing element overlay each other and the outward surfaces of the first housing element and the second housing element are exposed and face away from each other. In a fully deployed orientation, the display and the keyboard are in a side by side orientation.

In one exemplary embodiment, the hinge coupling is structurally configured to allow for rotation beyond 180 degrees of rotation so that in the fully deployed orientation the display is inclined relative to the keyboard.

In another embodiment, the electronic device further includes means for retaining the hinge so that the first and second housing elements are retained in a partially deployed orientation.

In one such embodiment, the hinge provides a means for holding the first and second housing elements in a partially deployed orientation which is between 30 and 150 degrees from the collapsed orientation, and, more typically, between 60 and 90 degrees from the collapsed orientation.

In another exemplary embodiment, the keyboard comprises a membrane having an illuminator positioned behind the membrane, such that without illumination, the keyboard has a substantially uniform appearance minimizing the appearance of any alpha numeric characters.

In one such exemplary embodiment, the keyboard without illumination has a substantially uniform appearance which substantially matches the appearance of the second housing element.

In certain embodiments, the electronic device further includes a battery housing accessible from the inside surface of one of the first and second housing elements.

Preferably, in certain embodiments, a speaker is positioned on the inside surface of the second housing element projecting audio signals substantially perpendicular to the inside surface of the second housing element. In some embodiments, the speaker may be positioned adjacent to the battery housing.

In another preferred embodiment, the electronic device further includes a speaker positioned on the inside surface of the second housing element projecting audio signals substantially perpendicular to the inside surface of the second housing element.

### BRIEF DESCRIPTION OF THE DRAWINGS

The disclosure will now be described with reference to the drawings wherein:

FIG. 1 of the drawings is a perspective view of an electronic device of the present disclosure shown in a fully collapsed orientation;

FIG. 2 of the drawings is a perspective view of an electronic device of the present disclosure shown in a fully deployed orientation;

FIG. 3 of the drawings is a perspective view of an electronic device of the present disclosure shown in a partially deployed orientation between the fully collapsed orientation and the fully deployed configuration;

FIG. 4 of the drawings is a back perspective view of an electronic device of the present disclosure shown in a fully deployed orientation;

FIG. 5 of the drawings is a side elevational view of an electronic device of the present disclosure shown in a fully deployed orientation; and

FIG. 6 of the drawings is a top plane view of an electronic device of the present disclosure showing, in particular, the hinge.

### DETAILED DESCRIPTION OF THE DISCLOSURE

While this invention is susceptible of embodiment in many different forms, there is shown in the drawings and described herein in detail a specific embodiment with the understanding that the present disclosure is to be considered as an exemplification and is not intended to be limited to the embodiment illustrated.

It will be understood that like or analogous elements and/or components, referred to herein, may be identified throughout the drawings by like reference characters. In addition, it will be understood that the drawings are merely schematic representations of the invention, and some of the components may have been distorted from actual scale for purposes of pictorial clarity.

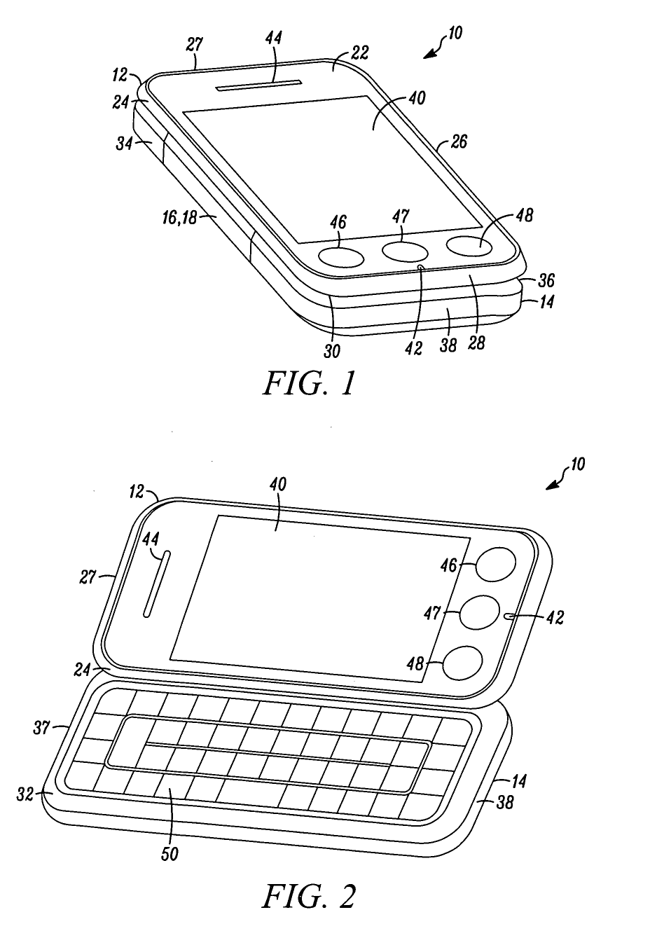

Referring now to the drawings and in particular to FIG. 1, the electronic device is shown generally at 10. In the embodiment shown, the electronic device comprises a mobile phone which has advanced features (often termed a smartphone). Of course, the electronic device is not limited to a mobile phone, and a number of different electronic devices, such as PDAs and the like, are likewise contemplated for use.

With continued reference to FIG. 1, the electronic device 10 comprises first housing element 12, second housing element 14, hinge 16 and means 18 for retaining the hinge in at least a deployed and collapsed configuration. It will be understood that in a collapsed configuration the two housing elements are positioned in an overlying orientation relative to each other. In a fully deployed orientation, the housing elements rotate relative to a predetermined degree of rotation. In the embodiment shown, it is preferred that the rotation exceeds 180 degrees.

The first housing element 12 is shown in FIGS. 1, 2 and 4 collectively, as comprising inward surface 20, outward surface 22, first side edge 24, second side edge 26 and end edges 27, 28. The first housing element comprises a substantially rectangular configuration with side edges 24, 26 being longer than end edges 27, 28. The outward surface 22 of the first housing element includes an electronic display 40, microphone 42, speaker 44 and buttons, such as buttons 46, 47, 48. By way of example only, and without limitation, the electronic display comprises an LCD or OLED display, although others are likewise contemplated. The electronic display is preferably also touch sensitive (either single touch or multi-touch).

The microphone is generally positioned at one end of the first housing element, or on an edge itself. The speaker is positioned on the opposing end of housing, opposite the microphone. Buttons may be provided on the outward surface, such as start call and end call buttons. Fewer or greater buttons may likewise be positioned on the outward surface 22 of the first housing element. It is contemplated that the first housing element has a length of approximately three to seven inches, a width of approximately two and a half to four inches and a thickness of approximately one eighth to three eighths thick. Of course, these sizes are merely illustrative of certain embodiments, and are not to be deemed as limiting. It will be understood that other larger or smaller sized housing elements are within the scope of the invention.

The second housing element 14 is shown in FIGS. 1 and 2, collectively, as comprising inward surface 30, outward surface 32, first side edge 34, second side edge 36, and end edges 37, 38. The second housing element comprises a substantially rectangular configuration which is generally similarly sized and shaped as the first housing element. In the embodiment shown, the first side edge 34 generally matches the first side edge 24 and are positioned in close proximity. Likewise, the second side edge of the housing elements generally match. The alignment of housing features is not to be deemed limiting and is only used for illustrative purposes. In certain embodiments, one of the elements may be larger or smaller than the other. With reference to FIG. 4, the inward surface 30 of the second housing element includes battery access door 60 which provides ingress into the battery cavity and, in turn, access to the battery. In certain embodiments, the case may be sealed and user access to the battery may be limited or fully precluded.

With continued reference to FIG. 4, a speaker 62 may be positioned on the inside surface of the second housing element so that the speaker projects sound in a generally outward direction from the inward surface of the second housing element. Advantageously, when in a deployed orientation, the speaker can provide sound in an outward direction. In a collapsed orientation, the sound is generally redirected by the first housing element such that the sound is directed substantially along the inward surface until exiting beyond the end edges and the side edge.

As is shown in FIG. 2, the outward surface 32 includes a keyboard positioned thereon. In certain embodiments, the keyboard comprises a membrane type keyboard featuring a backlit alpha-numeric display. In such a configuration, the keypad can be configured in a color that matches the remainder of the outward surface of the second housing element, and may include minor surface variations to define the different keys. As such, even from a close view, it is difficult to discern the existence of the keyboard on the outward surface of the second housing element. Of course, once the backlight is activated, the corresponding alpha-numeric character for each key becomes visible. Additional features, such as key outlines can also become visible at such time.

It is contemplated that the backlighting is activated automatically when the first housing element and the second housing element are in particular orientations (i.e., a fully deployed orientation). It is also contemplated that the back lighting is activated upon the entry of a particular sequence of keys on the keypad, or a particular key on the keypad. In still other embodiments, a button or key or switch may be provided on another surface (i.e., other than on the keyboard 50 itself or the outward surface of the second housing element) to toggle the backlight between the off and on positions.

It will be understood that in other configurations, a membrane keyboard can be provided without a backlight feature, wherein each of the keys are identified with a visible alpha-numeric character. In still other embodiments, keyboards with independent actuatable keys may be utilized in place of the membrane type keyboards. Other input devices such as morphing keypads with switchable characters or a second touchscreen display may also be used as input devices rather than the keyboard shown.

Hinge 16 is shown in FIG. 6 as comprising a first hinge component 70 formed proximate first edge 24 of the first housing element 12, a second hinge component 72 formed proximate first edge 34 of the second housing element 14 and hinge pin component 74 which pivotably couples the first hinge component to the second hinge component. The hinge components are configured such that in a collapsed configuration the inward surfaces of each of the first housing element and the second housing element face each other in substantially close abutment. In certain embodiments, such a substantially close abutment results in contact between the surfaces, or portions of the surfaces. In other embodiments, such a substantially close abutment results in a separation between the surfaces of a predetermined distance, such as, for example, and without limitation, a sixteenth of an inch or less.

The hinge 16 is shown as a single hinge. However, it will be understood that the hinge may comprise a plurality of discrete hinges extending along the first side edge of each of the first and second housing elements.

It is contemplated that the first and second hinge components 70, 72 may be integrally formed within the first and second housing elements, or portions thereof. In other embodiments, the first and second housing elements may be separate from the hinge components and may be coupled thereto through any one of a number of different attachment structures, such as adhesion, fasteners, interference fit, among others, or combinations of both. In still other embodiments, it will be understood that the hinge pin component may comprise multiple sub-components, which may be discrete elements, or which may be integrally formed with respective hinge components. In certain embodiments, a free-stop or friction hinge component, a cam-style hinge component, or other component may be used to connect the two housing elements and to maintain the angular position between them.

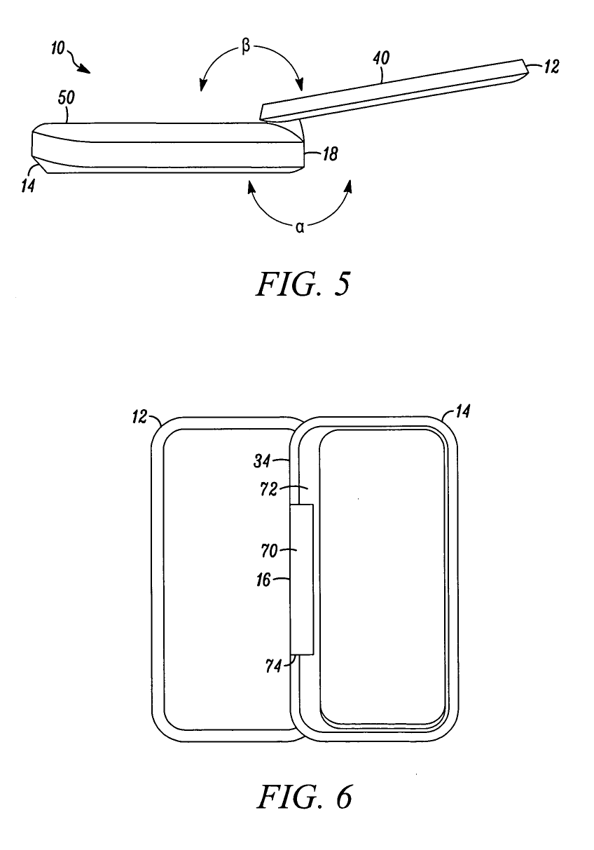

With reference to FIG. 5, the hinge 18 is configured to allow for rotation in excess of 180 degrees. As such, the outward surface 22 of the first housing element is angled relative to the outward surface 32 of the first housing element at an angle α so that the electronic display 40 is tilted relative to the keyboard 50. Such a configuration allows for an improved view of the electronic display while typing on the keyboard. Generally, rotation beyond 180 degrees so that the keyboard is tilted relative to the electronic display at an angle β of between 165 and 175 degrees appears to provide optimal positioning of the electronic display relative to the keyboard. Thus, such a configuration is defined as the fully deployed orientation.

Means 18 for retaining the hinge in a desired orientation may include a detent on one of the hinge components and a corresponding tab on the other of the hinge components. The detent and tab are positioned in such an orientation that they couple against each other to releasably preclude further rotation of the first housing element relative to the second housing element, or to make movement in either direction require an increased input force.

For example, it is advantageous to provide means for retaining the hinge in a fully collapsed orientation. As such, an increased force is required to open or initiate deployment of the electronic device from the fully collapsed orientation. Similarly, it is advantageous to provide means for retaining the hinge in a fully deployed orientation such that the device remains fully deployed while the user is typing on the keyboard while viewing the electronic display.

Finally, it is likewise advantageous to provide for a means for retaining the hinge in a position, or multiple positions between the fully collapsed and fully deployed orientations, for example, at a deployment angle of between 30 and 90 degrees from the collapsed orientation. Such an orientation allows for viewing of the electronic display while the second housing element is utilized as a base or support frame for the electronic display. For example, a user can position the outward surface of the second housing element on an outside surface, such as a table, and in a partially deployed orientation, the electronic display can be inclined at a deployment angle of between 30 and 150 degrees to provide optimal viewing of the electronic display (preferably between 60 and 90 degrees from the collapsed orientation). In such a configuration, the speaker is also substantially fully exposed so as to provide audio to accompany any video that is featured on the electronic display (of course, an audio port for connecting headphones and the like can be provided on any number of locations on either one of the first and second housing elements).

While the use of mating tabs and detents is contemplated, it is likewise contemplated that the retaining means 18 may comprise a friction retention wherein the first hinge component and the second hinge component are maintained through frictional forces. Thus, once placed in a particular orientation, user intervention is required so that the frictional force is overcome and so that the first housing element can be moved relative to the second housing element. When the user intervention ceases, the orientation is again maintained by the frictional forces between the hinge components. Additional biasing forces, such as through the use of springs and the like can serve to enhance the frictional forces. In other embodiments, the material properties and tolerances can be controlled so as to impart the necessary frictional forces, and to, in turn, preclude inadvertent movement of the first housing element relative to the second housing element without forces generated by user intervention.

Advantageously, the use of frictional forces allow for the positioning and maintaining of the first housing element relative to the second housing element at virtually any orientation between and including a fully deployed orientation and a fully collapsed orientation.

In operation, the electronic device is first provided in a collapsed orientation. In such an orientation which is shown in FIG. 1, the outward surface 22 of the first housing element and the outward surface 32 of the second housing element are visible and on opposing sides. Conversely, the inward surfaces of the respective first and second housing elements are positioned in an abutting relationship, and, as such are not visible. In such a collapsed orientation, the user can view the electronic display 40 as well as access the same through the touch screen interface on the electronic display. Additionally, buttons 46, 47, 48 allow for a user to provide additional input to the device. Additional features can be provided on the outward surface 22 of the first housing element.

As a user desires to utilize the keyboard, the user can rotate the first housing element relative to the second housing element about hinge 16. Generally, the user will rotate the two housing elements until such time that the fully deployed orientation is reached (as is shown in FIGS. 2 and 4). As set forth above, the fully deployed orientation is one wherein the hinge is rotated beyond 180 degrees with the electronic display tilted relative to the keyboard. In such a configuration, the user can utilize the keyboard while viewing the screen. The retaining means is employed to maintain the first housing element in the fully deployed orientation relative to the second housing element.

The user can actuate the backlight (or the backlight can be actuated automatically based upon the orientation of the first housing element relative to the second housing element). Once backlit, the user can more easily discern the location and identification of each of the keys of the keyboard. Of course, in certain embodiments, the keyboard may omit backlighting.

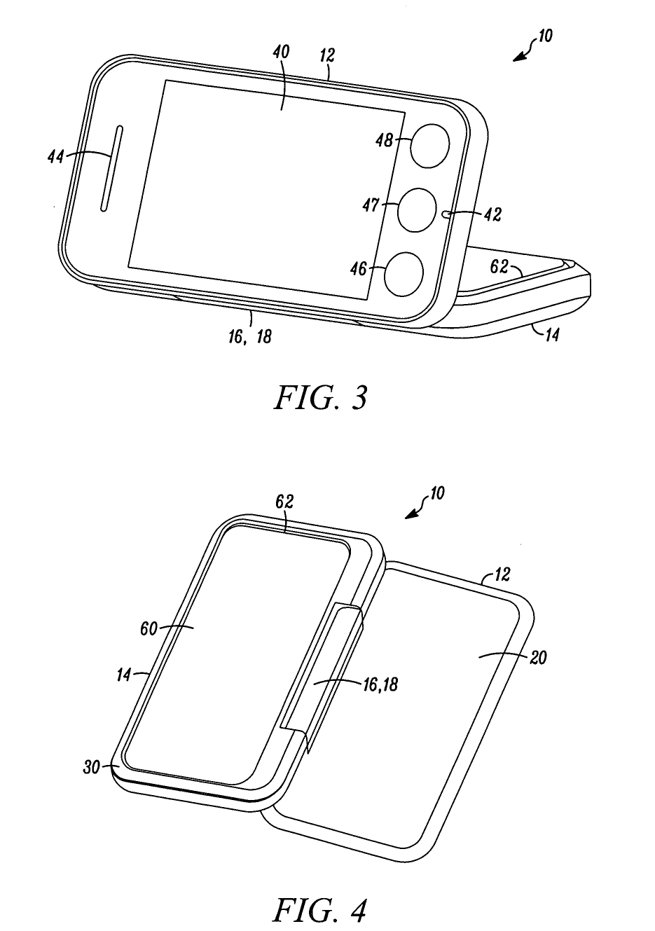

In yet other situations, and with reference to FIG. 3, such as when the user wishes to view the screen (without regard to utilizing the keyboard), the user can rotate the first housing element relative to the second housing element so that it is between the fully deployed and collapsed orientations. The outward surface 32 (FIG. 2) can then be placed on an outside surface, such as a desk, table or the like. The first housing element can be tilted as desired so as to position the electronic display into an orientation which enhances the viewability of the device. The retaining means is employed to maintain the orientation that is set by the user. In certain embodiments, the user may have a few (or even a single) orientation to select from. In other embodiments, wherein the retaining means relies upon friction, for example, an infinite number of orientations can be set by the user. In turn, the user can optimize the viewing angle.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. An electronic device comprising:
a first housing element having an inward surface and an outward surface and a side edge, the outward surface of the first housing element including an electronic display;
a second housing element having an inward surface and an outward surface and a side edge, the outward surface of the second housing element including a keyboard; and
a hinge coupling the first housing element and the second housing element about the respective side edges of the first and second housing elements, such that in a collapsed orientation the inward surfaces of the first housing element and the second housing element overlay each other and the outward surfaces of the first housing element and the second housing element are exposed and face away from each other, and, in a fully deployed orientation, the display and the keyboard are in a side by side orientation.

2. The electronic device of claim 1 wherein the first housing element, second housing element, and hinge are structurally configured to allow for rotation beyond 180 degrees of rotation so that in the fully deployed orientation the display is inclined relative to the keyboard.

3. The electronic device of claim 1 further comprising means for retaining the hinge so that the first and second housing elements are retained in a deployed orientation.

4. The electronic device of claim 3 wherein the hinge retaining means further includes means for retaining the hinge so that the first and second housing elements are retained in a partially deployed orientation which is between 30 and 150 degrees from the collapsed orientation.

5. The electronic device of claim 1 wherein the keyboard comprises a membrane having an illuminator positioned behind the membrane, such that without illumination, the keyboard has a uniform appearance, which, in turn, substantially hide a plurality of alpha numeric characters.

6. The electronic device of claim 5 wherein the keyboard without illumination has a substantially uniform appearance which substantially matches the appearance of the second housing element.

7. The electronic device of claim 1 further comprising a battery housing accessible from the inward surface of one of the first and second housing elements.

8. The electronic device of claim 7 further comprising a speaker positioned on the inside surface of the second housing element projecting audio signals substantially perpendicular to the inside surface of the second housing element, the speaker positioned adjacent to the battery housing.

9. The electronic device of claim 1 further comprising a speaker positioned on the inside surface of the second housing element projecting audio signals substantially perpendicular to the inside surface of the second housing element.

10. The electronic device of claim 1 wherein the keyboard is virtual and comprises a second electronic display having a touchscreen, such that a plurality of alpha numeric characters are selectively displayable on the second electronic display and selectable utilizing the touchscreen.

11. The electronic device of claim 1 wherein the electronic device comprises a mobile telephone.

12. An electronic device comprising:
a first housing element having an inward surface and an outward surface and a side edge, the outward surface of the first housing element including an electronic display;
a second housing element having an inward surface and an outward surface and a side edge, the outward surface of the second housing element including a keyboard and the inward surface of the second housing element including a speaker projecting audio signals outwardly therefrom;
a hinge coupling the first housing element and the second housing element about the respective side edges of the first and second housing elements, such that in a collapsed orientation the inward surfaces of the first housing element and the second housing element overlay each other and the outward surfaces of the first housing element and the second housing element are exposed and face away from each other, and, in a deployed orientation, the display and the keyboard are in a side by side orientation, wherein the hinge coupling is structurally configured to allow for rotation beyond 180 degrees of rotation so that in the deployed orientation the display is inclined relative to the keyboard; and
means for retaining the hinge so that the first and second housing elements are retained in a fully deployed orientation, and so that the first and second housing elements are retained in a partially deployed orientation which is between 30 and 150 degrees from the collapsed orientation.

13. The electronic device of claim 12 wherein the keyboard comprises a membrane having an illuminator positioned behind the membrane, such that without illumination, the keyboard has a uniform appearance that substantially hides a plurality of alpha numeric characters.

14. The electronic device of claim 13 wherein the keyboard without illumination has a substantially uniform appearance which may substantially match the appearance of the second housing element.

15. The electronic device of claim 12 further comprising a battery housing accessible from the inward surface of one of the first and second housing elements.

16. The electronic device of claim 15 further comprising a speaker positioned on the inside surface of the second housing element projecting audio signals substantially perpendicular to the inward surface of the second housing element, the speaker positioned adjacent to the battery housing.

17. The electronic device of claim 12 further comprising a speaker positioned on the inside surface of the second housing element projecting audio signals substantially perpendicular to the inside surface of the second housing element.

18. The electronic device of claim 12 wherein the keyboard is virtual and comprises a second electronic display having a touchscreen, such that a plurality of alpha numeric characters are selectively displayable on the second electronic display and selectable utilizing the touchscreen.
